(19) United States
(12) Patent Application Publication
(10) Pub. No.: US 2021/0225139 A1
(43) Pub. Date: Jul. 22, 2021

(54) LOCALIZATION AND PHASE DETECTION HAPTIC OUTPUT

(71) Applicant: Sentons Inc., Grand Cayman (KY)

(72) Inventors: Samuel W. Sheng, Saratoga, CA (US); Yenyu Hsieh, San Jose, CA (US); Mo-Hsi Edwin Su, Milpitas, CA (US); Herbert Huang, Mountain View, CA (US)

(21) Appl. No.: 17/146,241

(22) Filed: Jan. 11, 2021

Related U.S. Application Data
(63) Continuation-in-part of application No. 16/101,238, filed on Aug. 10, 2018.
(60) Provisional application No. 62/962,849, filed on Jan. 17, 2020.
(60) Provisional application No. 62/545,391, filed on Aug. 14, 2017.

(51) Int. Cl. G08B 6/00

(52) U.S. Cl. CPC G08B 6/00

(57) ABSTRACT

A haptic system is described. The haptic system includes a plurality of actuators, a plurality of receivers and at least one transmitter. Each of the actuators is configured to provide a vibration in response to an input signal. The receivers are configured to sense received vibrations from the actuators and to provide vibrational feedback based on the received vibrations. The transmitter(s) are configured to provide the input signal to each of the actuators. The receivers are coupled with the transmitter(s) and provide the vibrational feedback for the transmitter(s). The vibrational feedback indicates a phase difference between vibrations of the actuators at a particular location.

### CROSS REFERENCE TO OTHER APPLICATIONS

This application claims priority to U.S. Provisional Patent Application No. 62/962,849 entitled LOCALIZATION AND PHASE DETECTION HAPTIC OUTPUT filed Jan. 17, 2020 which is incorporated herein by reference for all purposes.

### BACKGROUND OF THE INVENTION

Mobile devices, such as smart phones, are increasingly desired to provide a haptic response to users. Linear resonant actuators (LRAs) are frequently utilized to provide this haptic response. However, depending upon the driving frequency for the LRA, the haptic response of an LRA may be too small for use in a mobile device. Further, the desired characteristics of the haptic response from the LRA may be difficult to achieve. Consequently, an improved mechanism for providing a haptic response, particularly in a mobile device, is desired.

### BRIEF DESCRIPTION OF THE DRAWINGS

Various embodiments of the invention are disclosed in the following detailed description and the accompanying drawings.

FIG. 1 is a diagram depicting an exemplary embodiment of a system for haptics including a linear resonant actuator and incorporating vibrational feedback.

FIG. 2 is a diagram depicting an exemplary embodiment of the frequency response of a linear resonant actuator.

FIG. 3 is a diagram depicting another exemplary embodiment of dynamic feedback system for haptics including a linear resonant actuator.

FIGS. 4A-4D are diagrams depicting exemplary embodiments of signals for of a linear resonant actuator incorporating vibrational feedback as incorporated in a mobile device.

FIG. 5 is a diagram depicting an exemplary embodiment of the dynamic frequency response of a linear resonant actuator incorporating vibrational feedback.

FIG. 6 is a flow chart depicting an exemplary embodiment of a method for providing a haptic response utilizing a linear resonant actuator incorporating vibrational feedback.

FIG. 7 is an embodiment of a haptic system utilizing feedback capable of localizing and providing phase information for haptic responses.

FIG. 8 is a flow chart depicting an exemplary embodiment of a method for utilizing feedback for localizing haptic responses.

FIG. 9 is a flow chart depicting an exemplary embodiment of a method for utilizing feedback for calibrating haptic responses.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Mobile devices, such as smart phones, are increasingly desired to provide a haptic response to users. Linear resonant actuators (LRAs) are frequently utilized to provide this haptic response. An LRA utilizes a spring-mass system having a resonant frequency at or near where k is the stiffness (e.g. Hooke's constant) of the spring and m is the mass attached to the spring. In order to drive the spring-mass system, currents and electromagnetic fields are used. In some cases, the mass is magnetic. The mass vibrates in response to a nearby changing current, for example a current driven through a voice coil. Alternatively, a current may be driven through a spring wound around a magnetic core. In such cases, the spring vibrates, which causes the mass to move. If the LRA is driven at or near the resonant frequency, the amplitude of displacement of the mass is sufficient to provide the desired haptic response. If the LRA is not driven at resonance, the mass may exhibit little movement and a small haptic response may be output. Thus, the haptic response of an LRA may be too small for use in a mobile device.

The LRA is also generally desired to output a particular haptic response profile. For example, the haptic response may be desired to have an amplitude versus time profile similar to a square pulse. Such a response may provide the user with the feel of the click of a button. Because of the frequency response of the LRA, however, the input signal used to achieve the desired haptic response may be complicated. For example, an input current pulse that is a square wave generally does not result in a mass displacement versus time that is also described by a substantially square wave.

To provide a haptic response, the LRA is calibrated. Calibration typically occurs during manufacture of the mobile or other device incorporating the LRA. During this calibration phase, the appropriate and typically complex input signal for the desired haptic response is determined. This input signal is then subsequently used to drive the LRA. Although calibrating the LRA may initially provide the desired haptic response, the appropriate input signal may drift based on aging of the mobile device, add-ons such as mobile device cases, the characteristics of the user and other attributes. Consequently, an improved mechanism for providing a haptic response is desired.

A mechanism for providing a haptic response is described. In some embodiments, a haptic system including an LRA, a receiver and a transmitter is provided. The haptic system may be incorporated into a mobile device or other device for which a haptic response is desired. The LRA has a characteristic frequency (e.g. a resonant frequency) and provides a vibration in response to an input signal. The receiver senses received vibration from the LRA. In some embodiments, the receiver may be a piezoelectric receiver. In some such embodiments, the piezoelectric receiver may also be operated as a touch sensor. The transmitter provides the input signal to the LRA. The receiver is coupled with the transmitter and provides vibrational feedback based on the received vibration. The input signal provided by the transmitter incorporates the vibrational feedback. In some embodiments, the haptic system includes a current sensor and a voltage sensor. The current sensor is coupled with the transmitter and senses a transmitter output current corresponding to the input signal. The voltage sensor is coupled with the transmitter and senses a transmitter output voltage corresponding to the input signal. Feedback for the transmitter includes the vibrational feedback, the transmitter output voltage and the transmitter output current. In some embodiments, a processor is coupled with the receiver, the current sensor and the voltage sensor. The processor provides for the transmitter a driving signal incorporating the feedback. For example, the processor may provide a difference between a desired haptic response and the received vibrations. The current and voltage sensors may be used to prevent the LRA from being overdriven.

A haptic system is described. The haptic system includes a plurality of actuators, a plurality of receivers and at least one transmitter. In some embodiments, the actuators include linear resonant actuators (LRAs). In some embodiments, the receivers include piezoelectric receivers. Each of the actuators is configured to provide a vibration in response to an input signal. The receivers are configured to sense received vibrations from the actuators and to provide vibrational feedback based on the received vibrations. The transmitter(s) are configured to provide the input signal to each of the actuators. The receivers are coupled with the transmitter(s) and provide the vibrational feedback for the transmitter(s). The vibrational feedback indicates a phase difference between vibrations of the actuators at a particular location. The phase difference may be used to provide a particular haptic response from the plurality of actuators at the particular location.

In some embodiments the system includes current sensor(s) and voltage sensor(s). The current sensor(s) are coupled with the transmitter(s) and are configured to sense transmitter output current(s) corresponding to the input signal. The voltage sensor(s) are coupled with the transmitter(s) and are configured to sense a transmitter output voltage corresponding to the input signal. Feedback for the transmitter(s) includes the vibrational feedback, the transmitter output voltage and the transmitter output current. The system may also include processor(s) coupled with the receivers, the current sensor and the voltage sensor. The processor(s) are configured to provide for the transmitter(s), driving signal(s) incorporating the feedback. The input signal may incorporate the vibrational feedback such that the phase difference may be used to provide the desired haptic response from the plurality of actuators at the particular location.

A method for generating a haptic response is also described. The method includes sensing received vibrations from actuators using receivers. The receivers may include piezoelectric receivers. Each of the actuators provides a vibration in response to an input signal. Feedback is provided for transmitter(s). The feedback includes vibrational feedback from the receivers based on the received vibrations. The vibrational feedback indicates a phase difference between vibrations of the actuators at a particular location. The method also includes providing from the transmitter the input signal(s) to each actuator, the input signal incorporating the vibrational feedback. This correction of the input signal using vibrational feedback may be carried out dynamically during use in order to generate an input signal that results in the desired vibrations from the LRA and, therefore, the desired haptic response.

In some embodiments, the method includes sensing a transmitter output current corresponding to the input signal and sensing a transmitter output voltage corresponding to the input signal. In such embodiments, providing the feedback for the transmitter(s) may include providing the vibrational feedback, providing the transmitter output voltage and providing the transmitter output current. In some embodiments, at least one driving signal incorporating the feedback is provided for the transmitter(s). In some embodiments, the method includes detecting a user-generated input and initially providing the input signal in response to the user-generated input.

A calibration method is also described. The calibration method includes providing from transmitter(s) an input signal to each of a plurality of actuators. The input signal is selected such that each of the actuators is excited in a non-observable mode. Received vibrations from the actuators are sensed using receivers. Each of the actuators provides a vibration in response to the input signal. Feedback for the transmitter(s) is provided. The feedback includes vibrational feedback from the receivers based on the received vibrations. The vibrational feedback indicates a phase difference between vibrations of the plurality of actuators at a particular location. The input signals may then be adjusted in order to provide the desired phase from the vibration of each actuator and, therefore, the desired haptic response.

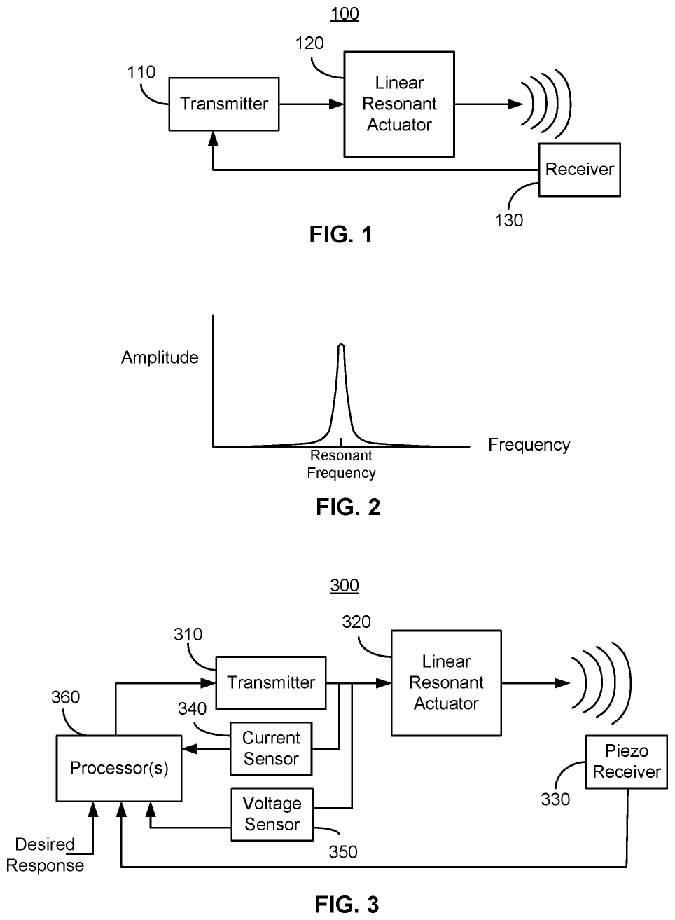

FIG. 1 is a diagram depicting an exemplary embodiment of haptic system 100 usable in a device such as a mobile device. For clarity, only certain components are shown and FIG. 1 is not to scale. The haptic system includes at least one transmitter 110, at least one linear resonant actuator (LRA) 120, and at least one receiver 130. In the embodiment shown in FIG. 1, haptic system includes one transmitter 110, one LRA 120 and one receiver 130. LRA 120 has a characteristic frequency (e.g. a resonant frequency) and provides a vibration in response to an input signal. An embodiment of the frequency response of LRA 120 is depicted in FIG. 2. The resonant frequency of LRA 120 may be at least five Hertz and not more than five hundred Hertz in some embodiments. For example, the resonant frequency may be two hundred Hertz.

In operation, transmitter 110 sends an input signal to LRA 120 to drive LRA 120. LRA 120 responds and provides initial output vibrations. The vibrations from LRA 120 propagate through the device in which haptic system 100 is incorporated. Receiver 130 senses received vibrations from LRA 120. In some embodiments, receiver 130 is a piezoelectric receiver. In some such embodiments, piezoelectric receiver 130 may also be operated as a touch sensor. When operated as a touch sensor, piezoelectric receiver 130 is driven by a signal. However, when used in connection with haptic system 100, receiver 130 may be considered to be used as a microphone. In response to a received vibration, receiver 130 provides vibrational feedback (feedback based on the received vibrations) for transmitter 110. More specifically, amplitude of the response, the envelope of the response and the phase may be sensed using receiver 130 and returned as vibrational feedback. In the embodiment shown, receiver 130 provides the vibrational feedback directly to transmitter 110. In other embodiments, the vibrational feedback is processed before being incorporated into a signal provided to transmitter 110. For example, the response of receiver 130 may be proportional to the received vibrations. The feedback provided to transmitter 110 may be based on a difference between the desired haptic response and the received vibrations. This feedback is incorporated into a (new) input signal provided by transmitter 110 to LRA 120. The new input signal should result in (new) haptic response by LRA 120 that is closer to the desired haptic response. Thus, the haptic response of LRA 120 is adjusted based upon the received vibrations at receiver 130 and the desired haptic response. Consequently, the desired haptic response may be achieved.

In some embodiments, haptic system 100 is used as part of a streamlined calibration mechanism during or after production. Consequently, each mobile device incorporating a haptic system may be individually calibrated. Further, haptic system 100 may be used in real time during actual usage of the corresponding device. In such an embodiment, haptic system 100 may dynamically adjust output of LRA 120 in real time. In such embodiments, haptic system 100 may account for differences in users, cases, wear, temperature and/or other issues that may otherwise reduce the haptic response from what is desired. Thus, using vibrational feedback, haptic system 100 may improve the haptic response in a mobile device.

FIG. 3 is a diagram depicting an exemplary embodiment of haptic system 300 usable in a device such as a mobile device. For clarity, only certain components are shown and FIG. 3 is not to scale. The haptic system includes at least one transmitter 310, at least one linear resonant actuator (LRA) 320, and at least one receiver 330. In the embodiment shown in FIG. 3, haptic system includes one transmitter 310, one LRA 320 and one receiver 330. Receiver 330 is a piezoelectric receiver. In some such embodiments, piezoelectric receiver 330 may also be operated as a touch sensor. In some embodiments, the resonant frequency of LRA 320 is at least 5 Hz and not more than 300 Hz. In such embodiments, the wavelength(s) of vibrations for LRA 320 are such that the location of piezoelectric receiver 330 in a smaller mobile device such as a smart phone is not important in providing vibrational feedback. However, in some embodiments, piezoelectric receiver 330 is desired to have a specific location, such as a desired location for a particular haptic response. Transmitter 310, LRA 320 and receiver 330 are analogous to transmitter 110, LRA 120 and receiver 130, respectively. In addition, haptic system 300 includes at least one current sensor 340, at least one voltage sensor 350 and one or more processors 360. For simplicity, only one current sensor 340, one voltage sensor 350 and one processor 360 are separately depicted.

Haptic system 300 functions in an analogous manner to haptic system 100. Transmitter 310 sends an input signal to LRA 320 to drive LRA 320. Current sensor 340 and voltage sensor 350 sense the current and voltage for the input signal. LRA 320 responds and provides initial output vibrations. The vibrations from LRA 320 propagate through the device in which haptic system 300 is incorporated. Piezoelectric receiver 330 senses received vibrations from LRA 320. In response to a received vibration, piezoelectric receiver 330 provides vibrational feedback (feedback based on the received vibrations) for transmitter 310. The vibrational feedback may simply be a measure of the received vibrations. Thus, piezoelectric receiver 330 functions in an analogous manner to receiver 130. This vibrational feedback is provided to processor 360 and/or other logic (not shown). Processor 360 may operate on the vibrational feedback, for example calculating a difference between the received vibrations and the desired haptic response. This difference is used to provide a driving signal to transmitter 310.

Processor 360 also receives from sensors 340 and 350 current and voltage feedback related to the input signal for LRA 320. Feedback from current sensor 340 and voltage sensor 350 may be used to ensure that LRA 320 is not overdriven. For example, processor 360 may limit or reduce the gain on signals input to transmitter 310. Processor 360 provides a new driving signal to transmitter 310. The new driving signal provided to transmitter 310 may be a combination of the previously provided signal, the vibrational feedback (e.g. a difference between the desired haptic response and the received vibrations from piezoelectric receiver 330), and any changes due to the sensed current and voltage. Transmitter 310 then provides a new input signal to LRA 320.

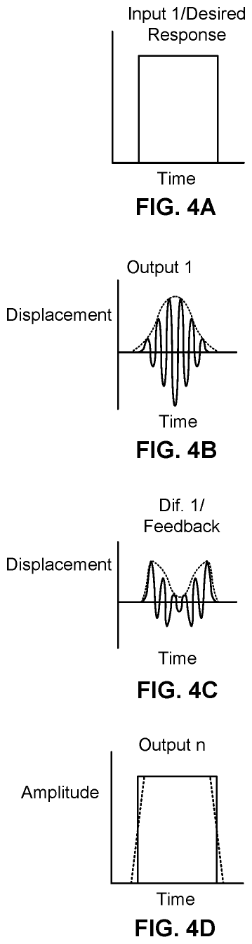

For example, FIGS. 4A-4D depict various signals during operation of haptic system 300. FIG. 4A depicts the envelope of the desired haptic response. An input signal having the same shape may also be provided from transmitter 310 to LRA 320 as an initial driving signal. The initial output of LRA 320 is shown in FIG. 4B, with the envelope indicated by a dashed line. Thus, a mass in LRA 320 oscillates at or near the resonant frequency of LRA 320. Piezoelectric receiver 330 senses the vibrations and provides this vibrational feedback to processor 360. Processor 360 determines the difference between the desired haptic response and the vibrational feedback/received vibrations from piezoelectric receiver 430. This difference is shown in FIG. 4C, with the envelope indicated by a dashed line. In addition, the sensed current and voltage for the signal driving LRA 320 are provided to processor 360, which determines whether to reduce the gain to transmitter 310. Processor 360 to transmitter 310 provides a control signal that takes into account the previous driving signal (e.g. FIG. 4A), vibrational feedback (e.g. the difference in FIG. 4C), current feedback and voltage feedback. Transmitter 310 provides an updated input signal to LRA 320. This updated input signal incorporates the previous driving signal, vibrational feedback from piezoelectric receiver 330, current feedback and voltage feedback This process continues during operation. FIG. 4D depicts an embodiment of the envelope of the (eventual) output of LRA 320. Thus, LRA 320 is driven to provide a haptic response analogous to the desired form shown in FIG. 4A. FIG. 4D also depicts a dashed line indicating the haptic response having a finite slope. Such a response may reduce spiking of current and/or voltage.

Thus, haptic system 300 may be used as part of a streamlined calibration mechanism during production and/or in real time during use of the device in which haptic system 300 is incorporated. Consequently, each mobile device incorporating a haptic system may be individually calibrated. Further, haptic system 300 may dynamically adjust output of LRA 320 in real time. In such embodiments, haptic system 300 may account for differences in users, cases, wear, temperature and/or other issues that may otherwise reduce the haptic response from what is desired. Consequently, the haptic response in the device incorporating haptic system 300 may be improved.

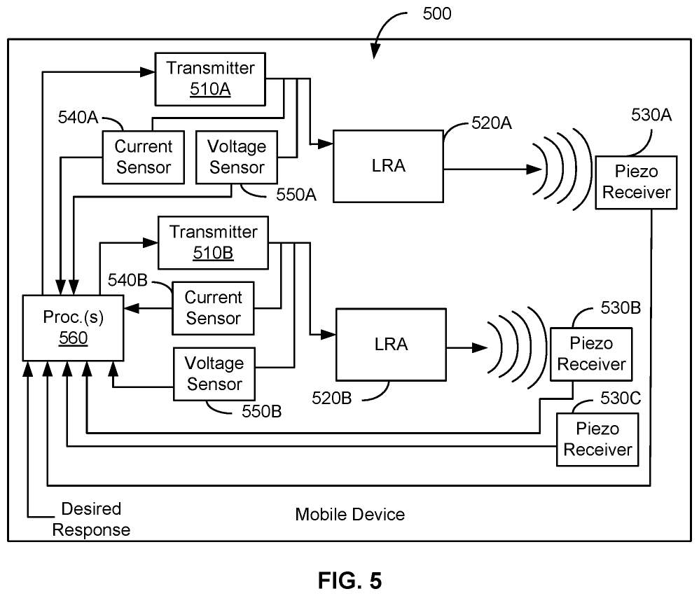

FIG. 5 is a diagram depicting an exemplary embodiment of haptic system 500 usable in a device such as a mobile device. For clarity, only certain components are shown and FIG. 5 is not to scale. The haptic system includes at least one transmitter 510, at least one linear resonant actuator (LRA) 520, at least one receiver 530, current sensor(s) 540, voltage sensor(s) 550 and processor(s) 560. In the embodiment shown in FIG. 5, haptic system includes two transmitters 510A and 510B (collectively or generically transmitter(s) 510), two LRAs 520A and 520B (collectively or generically LRA(s) 520) and receivers 530A, 530B and 530C (collectively receivers 530). Receivers 530 are piezoelectric receivers. Transmitter 510, LRAs 520 and receivers 530 are analogous to transmitter 110/310, LRA 120/320 and receiver 130/330, respectively. Current sensor(s) 540A and 540B (collectively or generically current sensor(s) 540), voltage sensor(s) 550A and 550B (collectively or generically voltage sensor(s) 550) and processor(s) 560 are analogous to current sensor(s) 340, voltage sensor(s) 350 and processor(s) 360. Although separate current sensors 540 and voltage sensors 550 are shown as sensing current and voltage output by transmitters 510 to for each LRA 520A and 520B, in some embodiments, shared current sensors and voltage sensors may be used for both LRAs 520. Haptic system 500 functions in an analogous manner to and may provide benefits analogous to haptic system 100 and/or 300. However, as indicated in FIG. 5, multiple LRAs 520 are driven (e.g. at their individual resonant frequency) and multiple piezoelectric receivers 530 sense the output of LRAs 520.

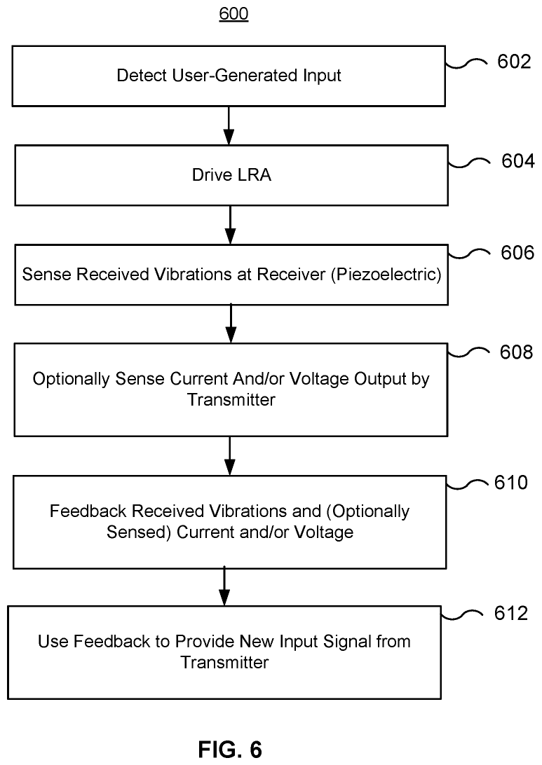

FIG. 6 is a flow chart depicting an exemplary embodiment of method 600 for using a haptic system having vibrational feedback. Method 600 may include steps that are not depicted for simplicity. Method 600 is described in the context of haptic system 300. However, method 600 may be used with other haptic systems including but not limited to systems 100 and 500.

User-generated input may be detected, at 602. For example, at 602 a user pressing a portion of the mobile device may be detected. In response, LRA 320 is driven, at 604. This may include transmitter 310 providing a driving signal to LRA 320. Receiver 330 senses received vibrations and provides vibrational feedback, at 606. Current and/or voltage may optionally be sensed by current sensor 340 and voltage sensor 350, at 608. Feedback incorporating the received vibrations and, optionally, sensed current and voltage is provided, at 610. In some embodiments, this feedback is provided to processor 360. The feedback is used to adjust the driving current, at 612. For example, the magnitude, frequency and/or phase may be adjusted for transmitter 310 may be tuned at 612. Similarly, the magnitude, frequency and/or phase (e.g. relative phase) for transmitters 510 may be adjusted at 612. This process continues during operation to provide the desired haptic response. Thus, the haptic response of a device may be improved.

In addition to or in lieu of providing a particular amplitude versus time profile of the haptic response, the haptic response may be localized at a desired region. Thus, the haptic output of one or more actuators, such as LRAs, may be desired to have a particular profile at a particular location on the device. For a single actuator, the mechanism described above may be used. In some embodiments, the receiver is desired to be located at or in proximity to the location/region at which the particular haptic response is desired. For multiple actuators, multiple receivers may be used.

A haptic system used in providing a desired haptic response at a particular location may include a plurality of actuators, a plurality of receivers and at least one transmitter. Each of the actuators provides a vibration in response to an input signal. The receivers sense received vibrations from the actuators and provide vibrational feedback based on the received vibrations. The transmitter(s) provide the input signal to each of the actuators. The receivers are coupled with the transmitter(s) and provide the vibrational feedback for the transmitter(s). The vibrational feedback indicates a phase difference between vibrations of the actuators at a particular location. In some embodiments, the actuators are LRAs. In some embodiments, the receivers are piezoelectric receivers. The phase difference in the vibrations is used to provide a particular haptic response from the actuators at the particular location. Thus, using the feedback, the vibrations of each of the actuators may be adjusted such that the vibrations from the actuators cohere in the desired manner at the particular location. For example, the vibrations may constructively interfere to provide a larger amplitude of vibration at the particular location and nowhere else, restricting the haptics excitation to a small region that can be dynamically defined by the processor. The desired profile of the haptic response (e.g. amplitude versus time) may be achieved at the particular location. In some embodiments, current and/or voltage sensor(s) are utilized to sense the output current and/or output voltage of the transmitter(s). The output current and/or output voltage are part of the input signal provided by the transmitter(s) to the actuators. The sensed output current and/or output voltage may be part of the feedback used in controlling the actuators. In some embodiments, the haptic system includes one or more processors. The processor(s) are coupled with the receivers, the current sensor(s) and the voltage sensor(s). The processor(s) provide for the transmitter(s), driving signal(s) incorporating the feedback. Thus, the input signal to each actuator incorporates the vibrational feedback such that the phase difference is used to provide the desired haptic response from the actuators at the particular location.

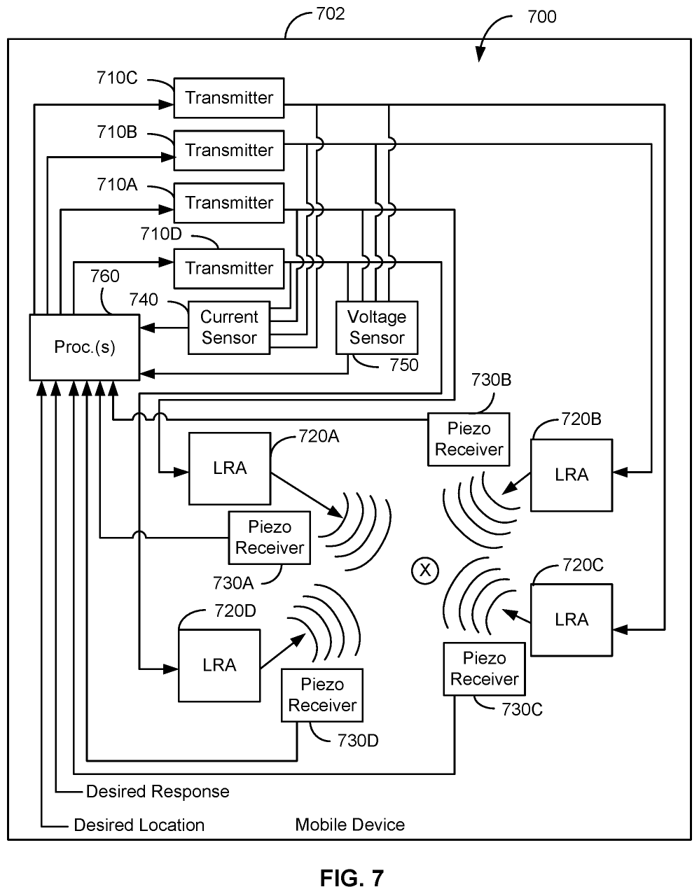

FIG. 7 is a diagram depicting an exemplary embodiment of haptic system 700 usable in device 702 such as a mobile device (e.g. a smart phone). For clarity, only certain components are shown and FIG. 7 is not to scale. Haptic system 700 includes transmitters 710A, 710B, 710C and 710D (collectively transmitters 710), linear resonant actuators (LRAs) 720A, 720B, 720C and 720D (collectively LRAs 720) and receivers 730A, 730B, 730C and 730D (collectively receivers 720). Haptic system 700 also includes one or more current sensors 740, voltage sensors 750 and processors 760. For clarity, only one current sensor 740, one voltage sensor 750 and one processor 760 is shown. In some embodiments, multiple current sensor(s), voltage sensor(s) and/or processor(s) might be used. Although described in the context of LRAs, in some embodiments other actuators might be used. Although described in terms of a certain number of LRAs 720, another number of LRAs may be used. For example, piezoelectric actuators might be used in place of LRAs 720. Receivers 730A, 730B, 730C and 730D correspond to LRAs 720A, 720B, 720C and 720D, respectively. In some embodiments, there is a one-to-one correspondence between the LRAs 720 and the receivers 730. In other embodiments, a different number of receivers 730 may be used for a particular number of LRAs 720. However, the number of receivers 730 is generally desired to be sufficient to be able to determine phase information at a particular location for each of the LRAs 720 such that LRAs 720 can be controlled to provide the desired haptic response at a particular location.

Receivers 730 are piezoelectric receivers in the embodiment shown. In some such embodiments, piezoelectric receivers 730 may also be simultaneously operated as touch sensors. Transmitters 710, LRAs 720, receivers 730, current sensor 740, voltage sensor 750 and processor 760 are analogous to transmitters 110/310/510, LRAs 120/320/520, receivers 130/330, current sensor(s) 340/540, voltage sensor(s) 350/550 and processor(s) 360/560, respectively. A single current sensor 740 and a single voltage sensor 750 are shown as sensing current and voltage output by transmitters 710 to all LRAs 720. In some embodiments, separate current and voltage sensors may be provided for each transmitter 710A, 710B, 710C and 710D and each LRA 720A, 720B, 720C and 720D. Haptic system 700 functions in an analogous manner to and may provide benefits analogous to haptic system 100, 300 and/or 500. Thus, the desired profile (e.g. amplitude of vibration versus time) of the haptic response may be achieved. In addition, haptic system 700 may be used to provide the desired haptic response at a particular location. As used herein, a particular location includes a region of a desired size. In the embodiment shown in FIG. 7, the haptic response is desired to be provided at the circled location marked X.

In operation, transmitters 710 send an input signal to each LRA 720A, 720B, 720C and 720D. Each of LRAs 720 responds and provides initial output vibrations. The vibrations from LRAs 720 propagate through device 702. Receivers 730 sense received vibrations from LRAs 720. In response to a received vibration, each of receivers 730 provides vibrational feedback (feedback based on the received vibrations) for transmitters 710. In some embodiments, a signal corresponding to the displacement versus time is provided from each of receivers 730. In the embodiment shown, receivers 730 provide the vibrational feedback to processor 760. In some embodiments, each receiver 730A, 730B, 730C and 730D is considered to provide vibrational feedback for a corresponding LRA 720A, 720B, 720C and 720D, respectively.

LRAs 720 are different distances and directions from location X. Thus, vibrations from different LRAs 720 generated at the same time may arrive at location X at different times. Consequently, the vibrations from LRAs 720 may be out of phase. Using the vibrational feedback from receivers 730, processor 760 determines the phase difference and delays between the vibrations from each LRA 720A, 720B, 720C and 720D at location X. Also using the vibrational feedback from each receiver 730A, 730B, 730C and 730D, processor 760 can triangulate the LRAs 720 for location X. Processor 760 provides to the appropriate transmitters 710A, 710B, 710C and 710D updated driving signals based on the haptic responses from receivers 730A, 730B, 730C and 730D, phase differences at location X and the desired haptic response at location X. Thus, the updated driving signal incorporates the received vibrations (envelopes and amplitudes) from LRAs 720, difference in phases between the responses at location X and the desired haptic response at the location. In the embodiment shown, the desired haptic response and desired location are provided to processor 760 via separate inputs. In some embodiments, the desired response and the corresponding location may be provided via the same input. In some embodiments, the updated driving signal is also based on the currents and voltages sensed by current sensor 740 and voltage sensor 750. As discussed above, use of the feedback from current sensor 740 and voltage sensor 750 helps ensure that LRAs 720 are not be overdriven by transmitters 710. Transmitters 710 provide input signals to LRAs 720 based on the updated driving signals. For example, the driving signals may be adjusted so that the input signals to LRAs 720 result in the phase differences and delays between some or all of the vibrations from LRAs 720 being reduced or eliminated.

In some embodiments, haptic system 700 is used as part of a calibration mechanism. The calibration may take place during or after manufacture. In some such embodiments, the input signals provided by transmitters 710 may be configured such that the vibrations of LRAs 720 are not perceptible by a user. Stated differently, the vibrations are non-observable. In some embodiments, the input signals provided by transmitters 710 result in vibrations of LRAs 720 are perceptible by a user, but may be smaller in amplitude than for a haptic response. Thus, the haptic response for LRAs 720 may be localized at location X without unduly disturbing a user. The appropriate driving signals to transmitters 710 for adjusting the phases of LRAs 720 may be determined and used during subsequent operation of device 702. In some embodiments, the driving signals for transmitters 710 determined during calibration may be used as initial driving signals during normal operation of haptic system 700. Thus, the driving signals may then be updated during use of haptic system 700.

In some embodiments, modulation can be introduced into the driving waveforms for vibration of the actuators. If such modulation is introduced, the vibrations from the actuators may still be constructively interfere at the desired location X. However, at locations away from X, the vibrations from the actuators may be less detectible by a user. In some such embodiments, the actuators used are piezoelectric actuators rather than LRAs. Consequently, the desired haptic response may be better localized at the desired location.

Consequently, a device incorporating haptic system 700 may be individually calibrated and haptic responses localized to a particular location. Further, haptic system 700 may be used in real time during actual usage of device 702 to provide localized haptic responses. In such embodiments, haptic system 700 may dynamically adjust output of LRAs 720 in real time. In such embodiments, haptic system 700 may account for differences in users, cases, wear, temperature and/or other issues that may otherwise reduce the haptic response from what is desired and/or change the phase differences between the vibrations from LRAs 720 at a particular location. Thus, using vibrational feedback, haptic system 700 may improve the haptic response in a mobile device.

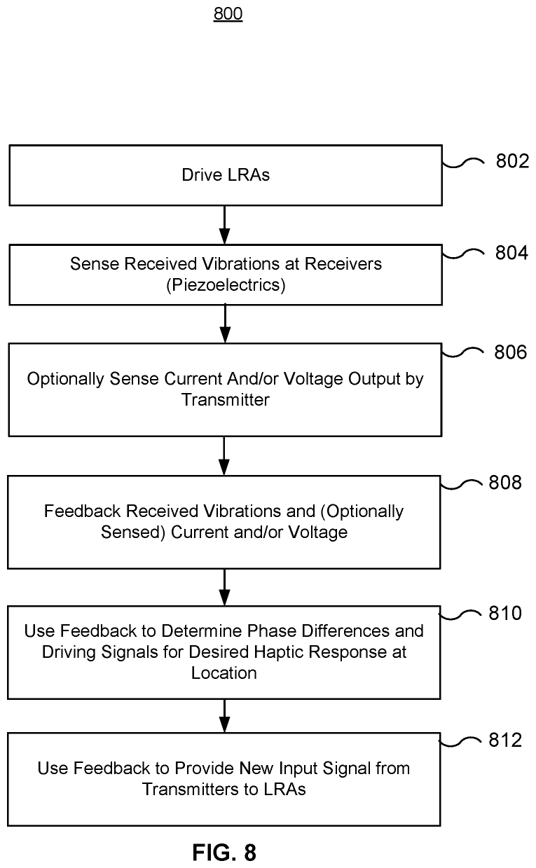

FIG. 8 is a flow chart depicting an exemplary embodiment of method 800 for using a haptic system having vibrational feedback and used in localizing a haptic response. Method 800 may include steps that are not depicted for simplicity. Method 800 is described in the context of haptic system 700. However, method 800 may be used with other haptic systems including but not limited to systems 100, 300 and 500. In some embodiments, method 800 is performed in response to user-generated input. In some embodiments, method 800 may be used in calibrating haptic system 700.

LRAs 720 are driven, at 802. This includes each transmitter 710A, 710B, 710C and 710D providing an input signal to a corresponding LRA 720A, 720B, 720C and 720D, respectively. LRAs 720 vibrate in response to the input signals. Receivers 730A, 730B, 730C and 730D sense received vibrations, at 804. Current and/or voltage may optionally be sensed by current sensor 740 and voltage sensor 750, at 806. This feedback (vibrational feedback, current sensed, and voltage sensed) is provided to processor 760, at 808. Using the feedback, the phase differences at the location X for the LRAs 730 are determined, at 808. The feedback is used to determine the new driving signals for transmitters 710 to provide the desired haptic response, at 810. The difference between the desired response of each LRA 720 and the vibration sensed by the corresponding receivers 730 as well as the phase differences at location X between the vibrations of LRAs 720 are thus determined and used in determining the new driving signals. Transmitters 710 provide new input signals for LRAs 720 based on these new driving signals, at 812. Thus, the vibrations output by LRAs 720 change. This process continues during operation to provide the desired haptic response at location X. Thus, the haptic response of a device at a particular location may be controlled.

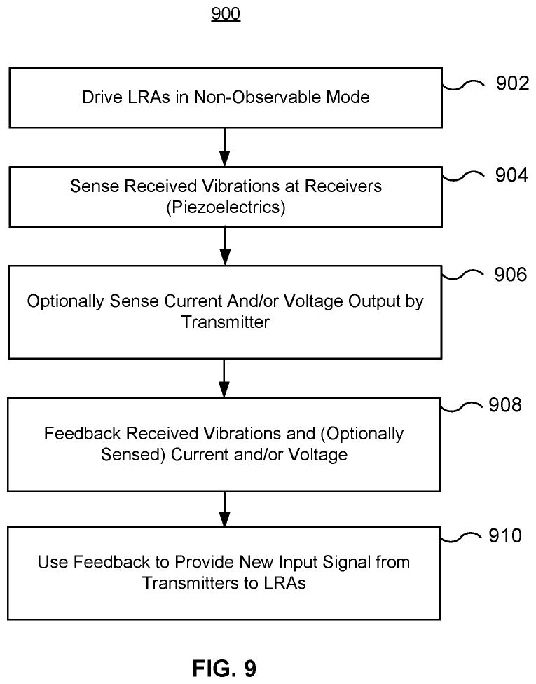

FIG. 9 is a flow chart depicting an exemplary embodiment of method 900 for using a haptic system having vibrational feedback and used in calibrating a haptic response. Method 900 may include steps that are not depicted for simplicity. Method 900 is described in the context of haptic system 700. However, method 900 may be used with other haptic systems including but not limited to systems 100, 300 and 500. In some embodiments, method 900 is performed in response to user-generated input. In some embodiments, method 900 may be used in calibrating haptic system 700.

LRAs 720 are driven such that the vibrations generated at a particular location (e.g. location X) are not perceptible by a user, at 902. This includes each transmitter 710A, 710B, 710C and 710D providing an input signal to a corresponding LRA 720A, 720B, 720C and 720D, respectively, such that the LRA 720A, 720B, 720C and 720D are excited in a non-observable mode. LRAs 720 vibrate in response to the input signals.

Receivers 730A, 730B, 730C and 730D sense received vibrations, at 904. Thus, although a user may not be able to perceive the vibrations, receivers 730A, 730B, 730C and 730D may sense the vibrations. Current and/or voltage may optionally be sensed by current sensor 740 and voltage sensor 750, at 906. This feedback (vibrational feedback and, optionally, sensed current and voltage) is provided to processor 760, at 908. Using the feedback, the phase differences at the location X for the LRAs 730 may also be determined at 908. The feedback is used to determine the new driving signals for transmitters 710 to provide the desired haptic response also at 908. The difference between the desired response of each LRA 720 and the vibration sensed by the corresponding receivers 730 as well as the phase differences at location X between the vibrations of LRAs 720 are thus determined and used in determining the new driving signals. Transmitters 710 provide new input signals for LRAs 720 based on these new driving signals, at 910. This process continues during operation to provide the desired haptic response at location X. Thus, the vibrations output by LRAs 720 may be calibrated without the user perceiving the vibrations. Consequently, the haptic response of a device at a particular location may be controlled without adversely affecting the user's experience.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A haptic system, comprising:
a plurality of actuators, each of the plurality of actuators configured to provide a vibration in response to an input signal;
a plurality of receivers configured to sense received vibrations from the plurality of actuators and to provide vibrational feedback based on the received vibrations;
at least one transmitter configured to provide the input signal to each of the plurality of actuators, the plurality of receivers being coupled with the at least one transmitter and providing the vibrational feedback for the at least one transmitter, the vibrational feedback indicating a to phase difference between vibrations of the plurality of actuators at a particular location.

2. The haptic system of claim 1 wherein the plurality of actuators include a plurality of linear resonant actuators (LRAs).

3. The haptic system of claim 1 wherein the plurality of receivers include a plurality of piezoelectric receivers.

4. The haptic system of claim 1 wherein the phase difference is used to provide a particular haptic response from the plurality of actuators at the particular location.

5. The haptic system of claim 1, further comprising:
a current sensor coupled with the at least one transmitter and configured to sense a transmitter output current corresponding to the input signal; and
a voltage sensor coupled with the at least one transmitter and configured to sense a transmitter output voltage corresponding to the input signal;
wherein feedback for the at least one transmitter includes the vibrational feedback, the transmitter output voltage and the transmitter output current.

6. The haptic system of claim 4, further comprising at least one processor coupled with the plurality of receivers, the current sensor and the voltage sensor, the processor configured to provide for the at least one transmitter, at least one driving signal incorporating the feedback.

7. The haptic system of claim 1, wherein the input signal incorporates the vibrational feedback such that the phase difference is used to provide the desired haptic response from the plurality of actuators at the particular location.

8. A method, comprising:
to sensing received vibrations from a plurality of actuators using a plurality of receivers, each of the plurality of actuators providing a vibration in response to an input signal;
providing feedback for at least one transmitter, the feedback including vibrational feedback from the plurality of receivers based on the received vibrations, the vibrational feedback indicating a phase difference between vibrations of the plurality of actuators at a particular location; and
providing from the at least one transmitter the input signal to each of the plurality of actuators, the input signal incorporating the vibrational feedback.

9. The method of claim 8, further comprising:
sensing a transmitter output current corresponding to the input signal;
sensing a transmitter output voltage corresponding to the input signal; and
wherein the providing the feedback for the at least one transmitter includes providing the vibrational feedback, providing the transmitter output voltage and providing the transmitter output current.

10. The method of claim 9, further comprising
providing for the at least one transmitter a least one driving signal incorporating the feedback.

11. The method of claim 8, wherein the plurality of receivers further includes a plurality of piezoelectric receivers.

12. The method of claim 8, further comprising:
detecting a user-generated input; and
initially providing the input signal in response to the user-generated input.

13. A calibration method, comprising:
providing from at least one transmitter an input signal to each of a plurality of actuators, to the input signal being selected such that each of the plurality of actuators is excited in a non-observable mode;
sensing received vibrations from the plurality of actuators using a plurality of receivers, each of the plurality of actuators providing a vibration in response to the input signal;
providing feedback for the at least one transmitter, the feedback including vibrational is feedback from the plurality of receivers based on the received vibrations, the vibrational feedback indicating a phase difference between vibrations of the plurality of actuators at a particular location.

14. The calibration method of claim 13, further comprising:
adjusting the input signal from the at least one transmitter to each of the plurality of actuators based on the feedback.
